(19) United States
(12) Patent Application Publication
(10) Pub. No.: US 2025/0380444 A1
(43) Pub. Date: Dec. 11, 2025

(54) GALLIUM NITRIDE-BASED HIGH-POWER RF DEVICE AND METHOD FOR FABRICATING THE SAME

(71) Applicant: Electronics and Telecommunications Research Institute, Daejeon (KR)

(72) Inventors: Sungjae CHANG, Daejeon (KR); HYUNWOOK JUNG, Daejeon (KR); Dong Min KANG, Daejeon (KR); Seong-il KIM, Daejeon (KR); YOUN SUB NOH, Daejeon (KR); Hokyun AHN, Daejeon (KR); Sang-Heung LEE, Daejeon (KR); Jong-Won LIM, Daejeon (KR)

(21) Appl. No.: 19/022,948

(22) Filed: Jan. 15, 2025

(30) Foreign Application Priority Data
Jun. 7, 2024 (KR) 10-2024-0074287

(51) Int. Cl. H10D 30/47; H01L 23/544; H10D 30/01; H10D 62/40; H10D 62/824; H10D 64/01; H10D 64/23; H10D 64/27

(52) U.S. Cl. CPC H10D 30/475; H01L 23/544; H10D 30/015; H10D 62/40; H10D 62/824; H10D 64/027; H10D 64/256; H10D 64/512; H10D 64/518; H01L 2223/54426

(57) ABSTRACT

Provided is a gallium nitride-based high-power RF device including a substrate including peripheral regions disposed in parallel in a first direction and an active region between the peripheral regions, a semiconductor layer, a barrier layer and a hexagonal boron nitride thin film layer sequentially laminated on the substrate, separation patterns disposed on the peripheral regions and penetrating through the hexagonal boron nitride thin film layer, the barrier layer, and the semiconductor layer, source/drain electrodes disposed on the semiconductor layer at edges of the active region and spaced apart from each other, and a T-gate electrode spaced apart from the source/drain electrodes on the barrier layer and disposed between the source/drain electrodes.

### CROSS-REFERENCE TO RELATED APPLICATIONS

This U.S. non-provisional patent application claims priority under 35 U.S.C. § 119 of Korean Patent Application No. 10-2024-0074287, filed on Jun. 7, 2024, the entire contents of which are hereby incorporated by reference.

### BACKGROUND

The present disclosure herein relates to a gallium nitride-based high-power RF device and a method for fabricating the same.

Due to the development of wireless communication technology, the amount of transmission data via satellite is greatly increasing. A communication RF device mounted on satellite is exposed to various cosmic rays to cause degradation in performance, so that erroneous operations may occur or devices may be damaged. Accordingly, a demand for a communication RF device having excellent cosmic ray tolerance is increasing.

A high-electron-mobility transistor (HEMT) provides a two-dimensional electron gas (2DEG) layer at a heterojunction interface due to polarization in heterogeneous semiconductor layers having different energy band gaps. The 2DEG layer may electrically connect source and drain electrodes to serve as a channel layer in which electrons can move, thereby being applied to a gallium nitride-based high-power RF device.

### SUMMARY

The present disclosure provides a gallium nitride-based high-power RF device having improved cosmic ray tolerance.

The present disclosure also provides a method for fabricating a gallium nitride-based high-power RF device having an improved yield.

An embodiment of the inventive concept provides a gallium nitride-based high-power RF device including: a substrate including peripheral regions disposed in parallel in a first direction and an active region between the peripheral regions; a semiconductor layer, a barrier layer and a hexagonal boron nitride thin film layer sequentially laminated on the substrate; separation patterns disposed on the peripheral regions and penetrating through the hexagonal boron nitride thin film layer, the barrier layer and the semiconductor layer; source/drain electrodes disposed on the semiconductor layer at edges of the active region and spaced apart from each other; and a T-gate electrode spaced apart from the source/drain electrodes on the barrier layer and disposed between the source/drain electrodes, wherein the T-gate electrode may include a first portion positioned downside, and a second portion positioned on the first portion, wherein a first width of the first portion in a first direction may be smaller than a second width of the second portion, at least a portion of the first portion may penetrate through the hexagonal boron nitride thin film layer to be in contact with the barrier layer, and a bottom surface of the second portion may be spaced apart from the hexagonal boron nitride thin film layer.

In an embodiment, the gallium nitride-based high-power RF device may further include a buffer layer between the substrate and the semiconductor layer, wherein the separation patterns may extend to penetrate the buffer layer.

In an embodiment, the source/drain electrodes may be spaced apart from the buffer layer and be respectively spaced apart from the separation patterns.

In an embodiment, the gallium nitride-based high-power RF device may further include an alignment key spaced apart from the separation patterns on the peripheral regions and penetrating through the hexagonal boron nitride thin film layer to be in contact with the barrier layer.

In an embodiment, the thickness of the hexagonal boron nitride thin film layer may be about 1 nm to about 5 nm.

In an embodiment, the gallium nitride-based high-power RF device may further include a two-dimensional electron gas layer disposed adjacent to the barrier layer and on the upper portion of the semiconductor layer.

In an embodiment, the source/drain electrodes may penetrate through the two-dimensional electron gas layer to extend to the semiconductor layer.

In an embodiment, the gallium nitride-based high-power RF device may further include contact pads respectively being in contact with top surfaces of the source/drain electrodes.

In an embodiment of the inventive concept, a method for fabricating a gallium nitride-based high-power RF device includes: sequentially providing a buffer layer, a semiconductor layer, and a barrier layer on a substrate including peripheral regions and an active region; providing a hexagonal boron nitride thin film layer on the barrier layer; providing a first protection layer on the hexagonal boron nitride thin film layer; providing, on the peripheral regions, an alignment key penetrating through at least a portion of each of the first protection layer and the hexagonal boron nitride thin film layer on the peripheral regions; providing, at edges of the active region, metal patterns penetrating through at least a portion of each of the first protection layer and the hexagonal boron nitride thin film layer; removing the first protection layer on the hexagonal boron nitride thin film layer, the alignment key, and the metal patterns; performing a thermal process to provide ohmic contact between the metal patterns and the semiconductor layer and change the metal patterns to source/drain electrodes; providing a second protection layer to cover the hexagonal boron nitride thin film layer, the alignment key, and the metal patterns; providing a T-gate electrode penetrating at least a portion of each of the second protection layer and the hexagonal boron nitride thin film layer between the source/drain electrodes; and removing the second protection layer.

In an embodiment, the providing of the alignment key may include removing at least a portion of the hexagonal boron nitride thin film layer by dry etching to provide a first hole, and the alignment key is disposed in the first hole.

In an embodiment, the method may further include, prior to the providing of the second protection layer and after the providing of the source/drain electrodes: providing a third protection layer; etching the third protection layer on the peripheral regions; providing separation patterns defining the active region between the alignment key and the source/drain electrode on the peripheral regions; and removing the third protection layer.

In an embodiment, the removing of the third protection layer may be performed by wet etching.

In an embodiment, the method may further include, prior to the providing of the T-gate electrode: removing the second protection layer on the source/drain electrodes to expose top surfaces of the source/drain electrodes; and providing contact pads respectively being in contact with the top surfaces of the source/drain electrodes.

In an embodiment, the hexagonal boron nitride thin film layer may be provided at a temperature of about 1000° C. to about 1500° C. using metal organic chemical vapor deposition (MOCVD).

In an embodiment, the removing of the first protection layer may be performed by wet etching.

In an embodiment, the removing of the second protection layer may be performed by wet etching.

In an embodiment, the providing of the metal patterns may include removing at least a portion of the hexagonal boron nitride thin film layer by dry etching to provide second holes, wherein the metal patterns may be disposed in the second holes.

In an embodiment, the providing of the T-gate electrode may include removing at least a portion of the hexagonal boron nitride thin film layer by dry etching to provide a third hole, wherein the T-gate electrode may be disposed in the third hole.

In an embodiment, the thermal process may be performed at a temperature of about 500° C. to about 1000° C.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a cross-sectional view of a gallium nitride-based high-power RF device according to an embodiment of the inventive concept; and

FIGS. 2A to 2R are cross-sectional views sequentially showing a fabrication method for a gallium nitride-based high-power RF device according to embodiments of the inventive concept.

### DETAILED DESCRIPTION

However, the inventive concept is not limited to the following embodiments and may be embodied in different ways, and various modifications may be made thereto. The embodiments are just given to provide complete disclosure of the inventive concept and to provide thorough understanding of the inventive concept to those skilled in the art. In the accompanying drawings, the sizes of the elements may be greater than the actual sizes thereof, for convenience of description, and the scales of the elements may be exaggerated or reduced.

The terminology used herein is for the purpose of describing particular embodiments only and is not intended to limit the scope of the present disclosure. Unless otherwise defined, all terms used herein have the same meaning as commonly understood by one of ordinary skill in the art to which this invention pertains.

The terminology used herein is for the purpose of describing particular embodiments only and is not intended to limit the scope of the present disclosure. As used herein, the singular forms “a”, “an” and “the” are intended to include the plural forms as well, unless the context clearly indicates otherwise. It will be further understood that the terms “comprises” and/or “comprising” used herein specify the presence of stated components, operations and/or elements but do not preclude the presence or addition of one or more other components, operations and/or elements.

It will be understood that, in the present specification, when a layer is referred to as being “on” another layer, it may indicate that the layer is directly on the other layer or that another layer(s) is present therebetween.

Although the terms first, second, third etc. may be used herein to describe various regions, and films (or layers) etc., the regions and films (or layers) are not to be limited by the terms. The terms may be used herein only to distinguish one region or layer) from another region or layer. Therefore, a part referred to as a first part in one embodiment can be referred to as a second part in another embodiment. An embodiment described and exemplified herein includes a complementary embodiment thereof. Like reference numerals refer to like elements throughout.

Embodiments of the inventive concept will be described below in more detail with reference to the accompanying drawings.

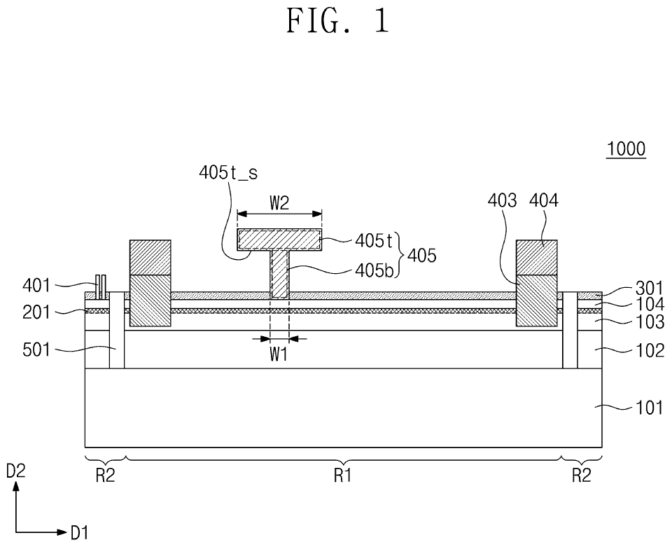

FIG. 1 is a cross-sectional view of a gallium nitride-based high-power RF device according to an embodiment of the inventive concept.

Referring to FIG. 1, the gallium nitride-based high-power RF device 1000 may include a substrate 101, a buffer layer 102, a semiconductor layer 103, a barrier layer 104, and a hexagonal boron nitride thin film layer 301 that are sequentially laminated. The substrate 100 may include an active region R1 and peripheral regions R2 arranged in parallel in a first direction D1.

The substrate 101 may include, for example, at least one of SiC, Si, sapphire, diamond, or GaN. However, the embodiment of the inventive concept is not limited thereto and the substrate 101 may include materials that may grow the semiconductor layer and the barrier layer.

The buffer layer 102 may be disposed on the substrate 101. The buffer layer 102 may be a layer for mitigating the differences in lattice constants and thermal expansion coefficients between the substrate 101 and the semiconductor layer 10. The buffer layer 102 may include, for example, a group III-V semiconductor compound including at least one of AlN, InN, GaN, AlGaN, InGaN, AlInN, AlGaInN, or GaAs.

The semiconductor layer 102 may be disposed on the buffer layer 102. The semiconductor layer 102 may include, for example, a group III-V semiconductor compound including at least one of AlN, InN, GaN, AlGaN, InGaN, AlInN, AlGaInN, or GaAs. The semiconductor layer 103 may include, for example, silicon. However, the embodiment of the inventive concept is not limited thereto, and the semiconductor layer 103 may include materials that cause a two-dimensional electron gas layer 201 to be provided inside the semiconductor layer 103. The semiconductor layer 103 may be an undoped layer, but in some cases, include a small amount of impurities.

The barrier layer 104 may be disposed on the semiconductor layer 103. The barrier layer 104 may be heterojunctioned with the semiconductor layer 103. When the semiconductor layer 103 is heterojunctioned with the barrier layer 104, polarization occurs in the interface to cause the two-dimensional electron gas layer 201 to be provided in the semiconductor layer 103. The two-dimensional electron gas layer 201 may be disposed adjacent to the barrier layer 104 and on the upper portion of the semiconductor layer 103. The two-dimensional electron gas layer 201 may electrically connect source/drain electrodes 403 to be described below, and serve as a channel in which electronics move.

The barrier layer 103 may include, for example, a nitride including at least one of Al, Ga, In, or B. The barrier layer 104 may include a single layer or multi-layer structure for increasing the density of and the electronic mobility in the two-dimensional electron gas layer 201. The barrier layer 104 may include a small amount of impurities or may not include impurities. The semiconductor layer 103 and the barrier layer 104 may include semiconductor materials of different lattice constants, and the barrier layer 104 may have a wider band gap than the semiconductor layer 103.

Although not shown, an interfacial layer may be provided between the semiconductor layer 102 and the barrier layer 104. The interfacial layer may influence the polarizations of the semiconductor layer 103 and the barrier layer 104 to increase the density of and the electron mobility in the two-dimensional electron gas layer 201.

The hexagonal boron nitride thin film layer 301 may be disposed on the barrier layer 104. The hexagonal boron nitride thin film layer 301 may include a nitride include semiconductor materials. The hexagonal boron nitride thin film layer 301 may include hexagonal boron nitrides (h-BNs). Accordingly, the hexagonal boron nitride thin film layer 301 may have the excellent interface characteristics such as electrical insulation, high thermal conductivity, and chemical stability. The hexagonal boron nitride thin film layer 301 may have the thickness of, for example, about 1 nm to about 5 nm. The thin thickness of the hexagonal boron nitride thin film layer 301 may improve the cosmic resistance of the hexagonal boron nitride thin film layer 301.

The gallium nitride-based high-power RF device 1000 according to the inventive concept may use the hexagonal boron nitride thin film layer 301 as an oxide film or a protection film to minimize the occurrence of total ionizing radiation dose (or total ionizing dose (TID)) effects due to cosmic radiation. Thus, the gallium nitride-based high-power RF device 1000 having high resistance to the cosmic radiation may be provided. The hexagonal boron nitride thin film layer 301 may be identified by, for example, an energy dispersive X-ray spectroscopy (EDS) analysis using a focused ion beam (FIB) apparatus and a transmission electron microscope (TEM).

The source/drain electrodes 403 may be disposed on the active region R1 of the semiconductor layer 103. The source/drain electrodes 403 may be spaced apart from each other at the edges of on the active region R1 of the semiconductor layer 103. The source/drain electrodes 403 may be disposed to penetrate through the barrier layer 104, the two-dimensional electron gas layer 201, and the hexagonal boron nitride thin film layer 301 to extend into the semiconductor layer 103. The source/drain electrodes 403 may not penetrate through the substrate 101 and the buffer layer 102, and be spaced apart from the buffer layer 102. The source/drain electrodes 403 may include, for example, at least one of Ti, Al, Ni, Au, Pd, Cu, Co, or Pt, or an alloy thereof. The source/drain electrodes 403 may include a metal silicide.

Contact pads 404 may be respectively disposed on the source/drain electrodes 403. The contact pads 404 may be respectively in contact with the source/drain electrodes 403. The contact pads 404 may include, for example, at least one of Ti, Al, Ni, Au, Pd, Cu, Co, or Pt, or an alloy thereof.

A T-gate electrode 405 may be spaced apart from each of the source/drain electrodes and disposed between the source/drain electrodes 403. The T-gate electrode 405 may include a first portion 405b and a second portion 405t positioned on the first portion 405b. A second width W2 of the second portion 405t in the first direction D1 may be larger than a first width W1 of the first portion 405b. A portion of the first portion 405b may penetrate through the hexagonal boron nitride thin film layer 301, and the bottom surface of the first portion 405b may contact the barrier layer 104. Thereby, the distance between the T-gate electrode 405 and the two-dimensional electron gas layer 201 is short to improve the electrical characteristics of the gallium nitride-based high-power RF device 1000. The bottom surface 405t_s of the second portion 405t may be spaced apart from the hexagonal boron nitride thin film layer 301. The T-gate electrode 405 may include, for example, at least one of Ti, Al, Ni, Au, Pd, Cu, Co, or Pt, or an alloy thereof.

Separation patterns 501 separating the active region R1 from the peripheral regions R2 may be disposed on the substrate 101. The separation patterns 501 may be disposed on the peripheral regions R2 to define the active region R1. The separation patterns 501 may penetrate through the buffer layer 102, the semiconductor layer 103, the barrier layer 104, the two-dimensional electron gas layer 201, and the hexagonal boron nitride thin film layer 301. The separation patterns 501 may not penetrate through the substrate 101. The separation patterns 501 may be spaced apart from the source/drain electrodes 403.

An alignment key 401 may be disposed on at least one of the peripheral regions R2. The alignment key 401 may be used to align various layers. The alignment key 401 may include one or more keys. The alignment key 401 may be spaced apart from the separation patterns 501. The alignment key 401 may penetrate through the hexagonal boron nitride thin film layer 301 to be disposed on the barrier layer 104. The alignment key 401 may not penetrate through the barrier layer 104. The alignment key 401 may be in contact with the barrier layer 104. The level of the top surface of the alignment key 401 in the second direction D2 may be higher than that of the hexagonal boron nitride thin film layer 301. The alignment key 401 may include, for example, Ni or Ag.

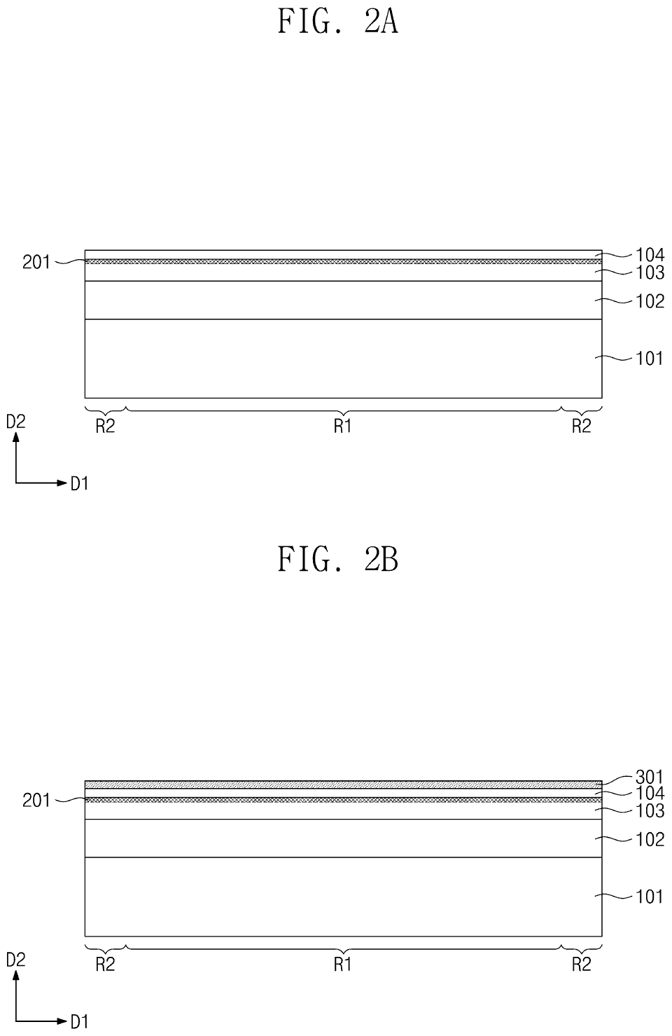

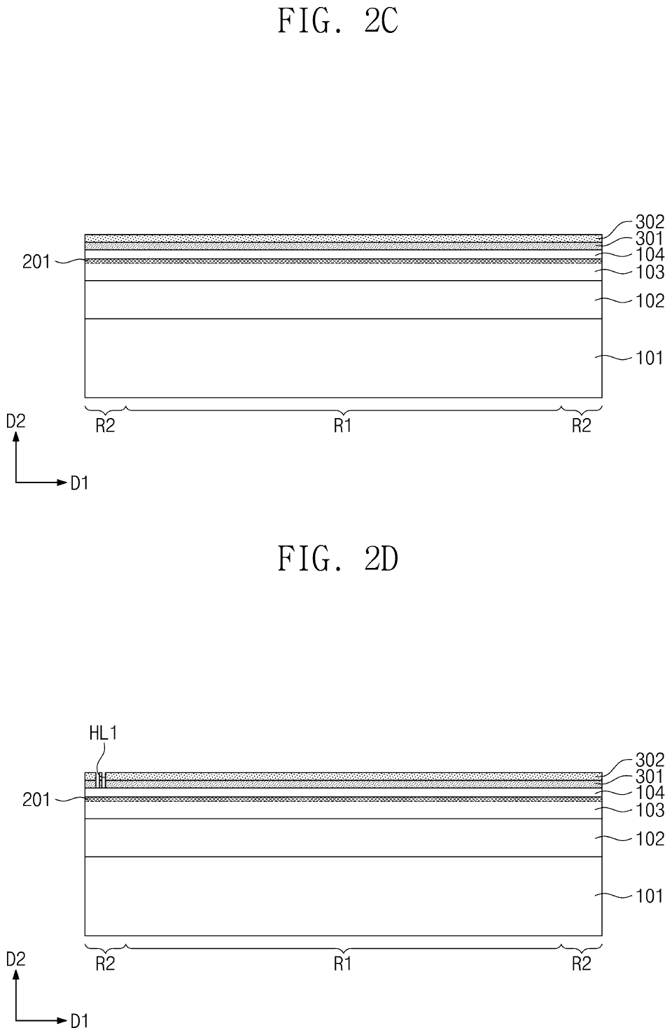

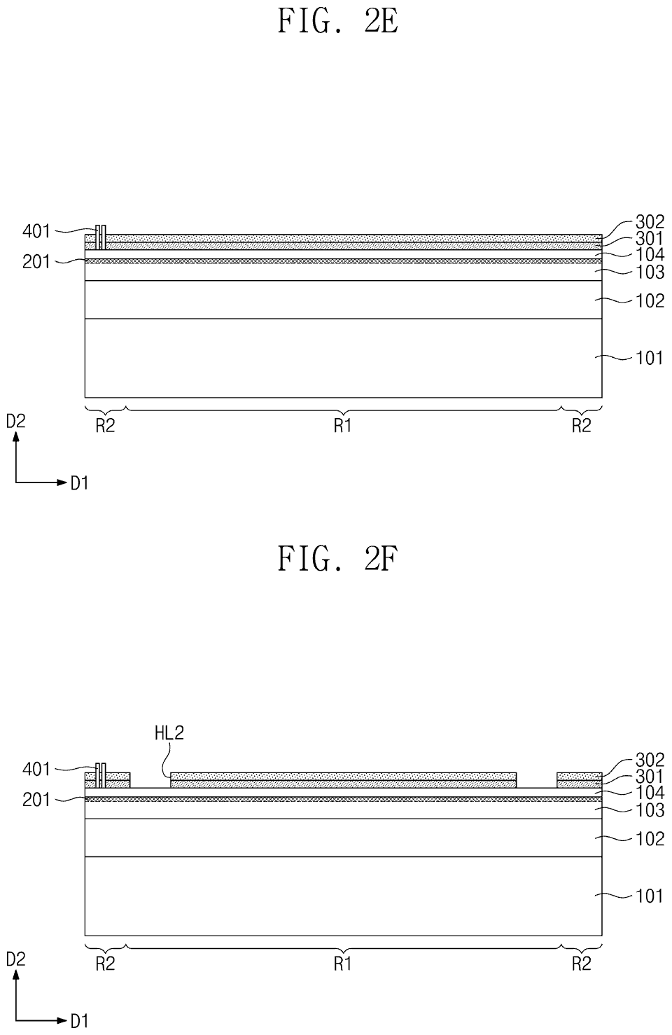

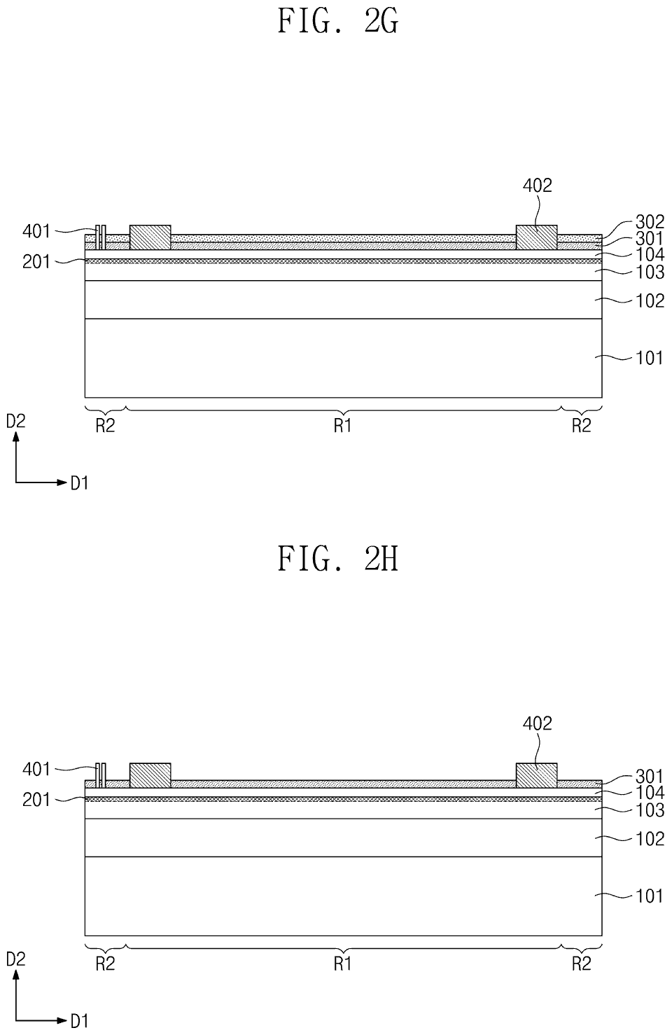

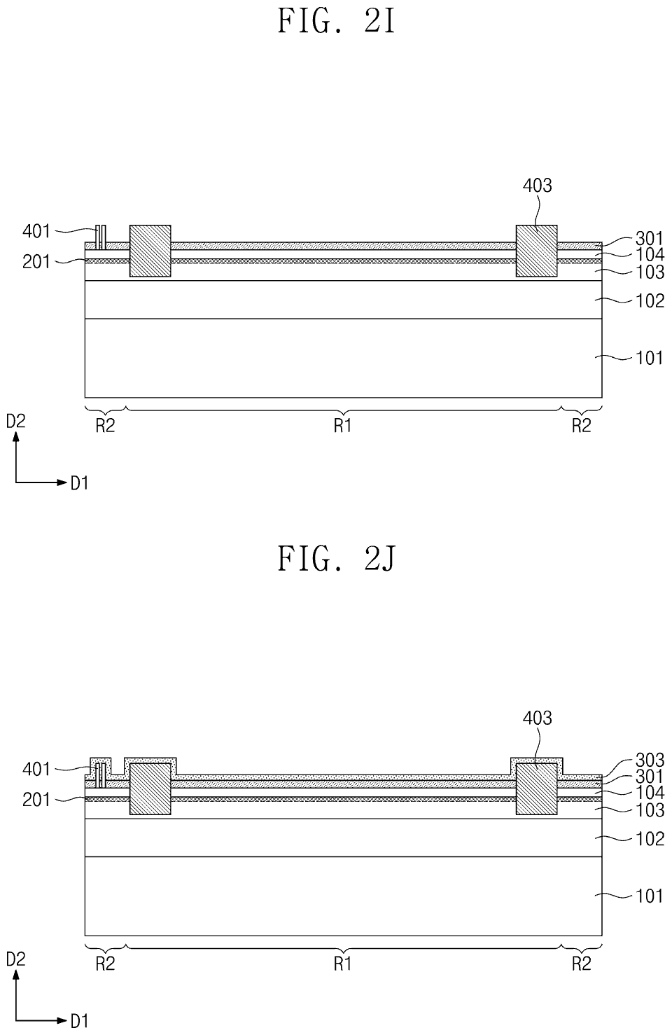

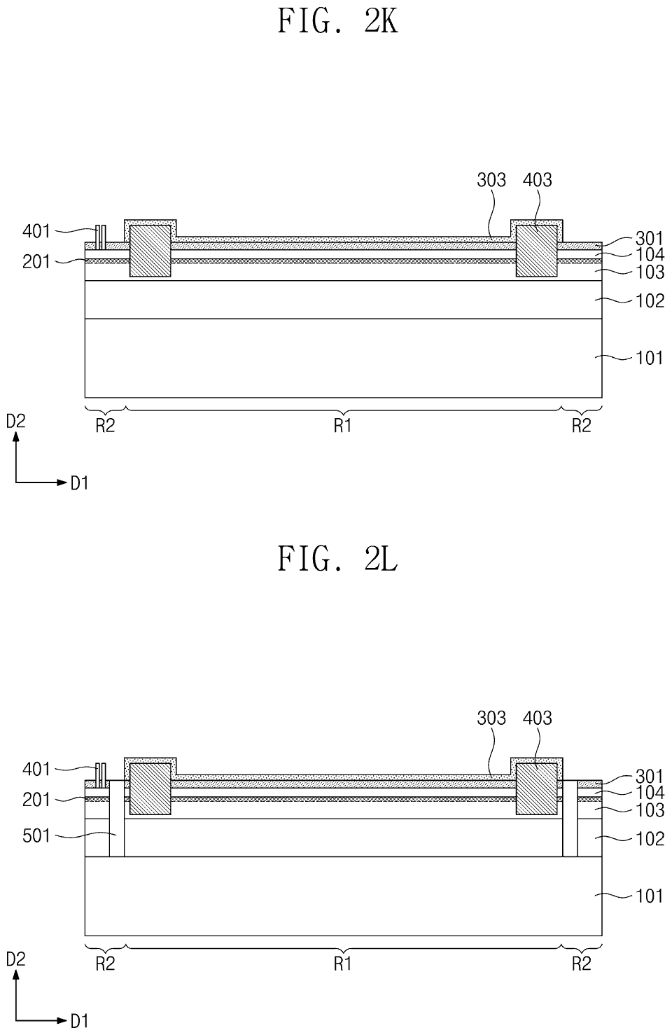

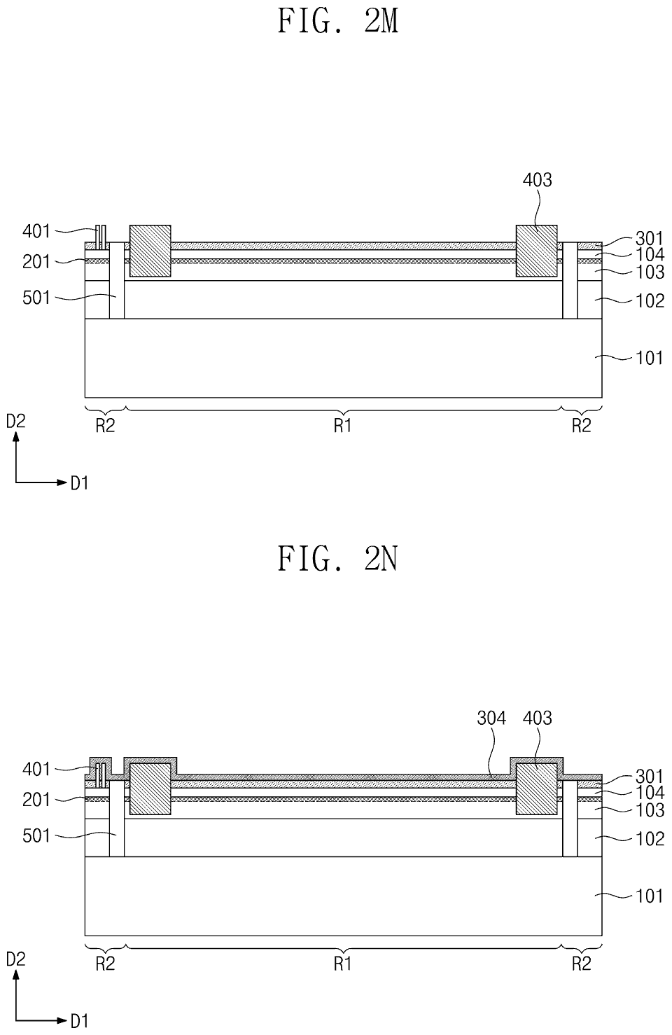

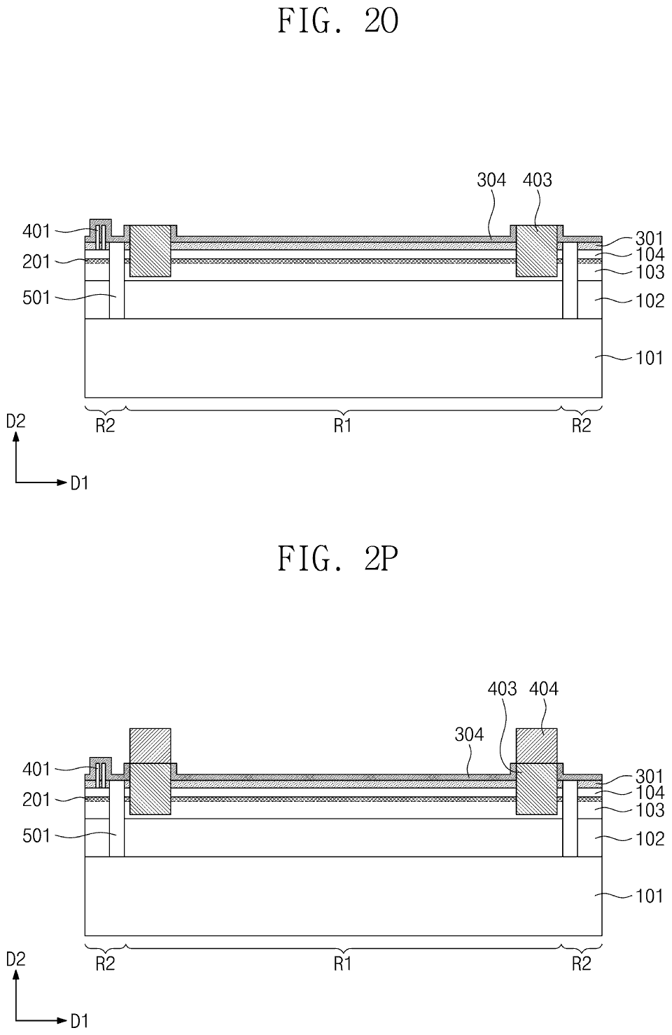

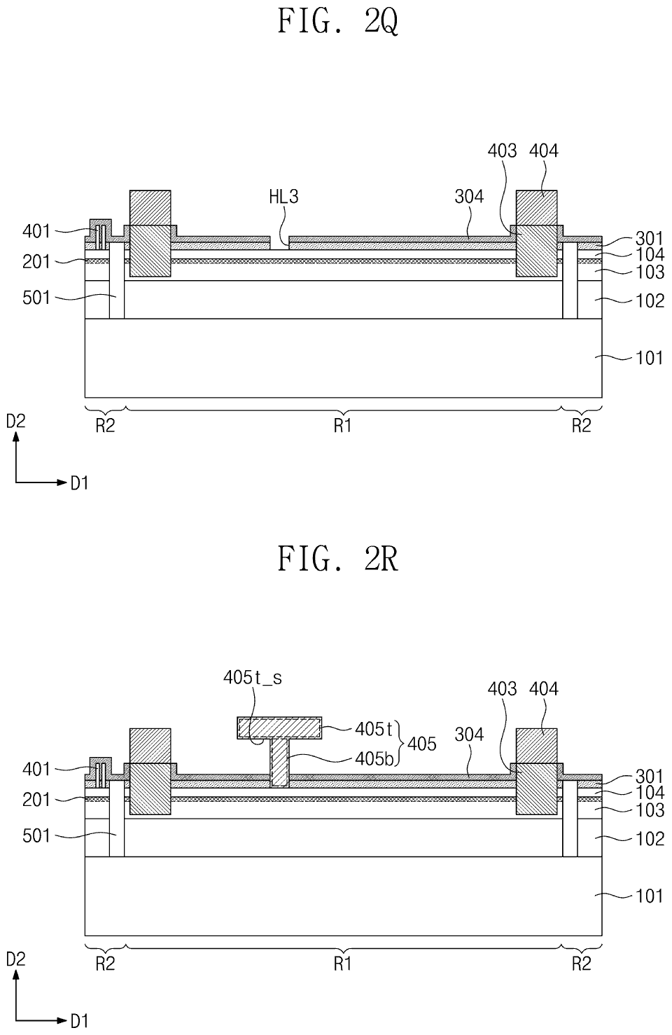

FIGS. 2A to 2R are cross-sectional views sequentially showing a method for fabricating the gallium nitride-based high-power RF device according to embodiments of the inventive concept.

Referring to FIG. 2A, the substrate 101, the buffer layer 102, the semiconductor layer 103, and the barrier layer 104 may be sequentially provided. Each of the substrate 101, the buffer layer 102, the semiconductor layer 103, and the barrier layer 104 may include the active region R1 and the peripheral regions R2.

Here, the barrier layer 104 may be heterojunctioned with the semiconductor layer 103. When the semiconductor layer 103 is heterojunctioned with the barrier layer 104, charges, spins, orbitals, and the like may be strongly cross-coupled and the polarizations may occur at the interface between the barrier layer 104 and the semiconductor layer 103, thereby providing the two-dimensional electron gas layer 201 at the semiconductor layer 103. The two-dimensional electron gas layer 201 may be disposed adjacent to the barrier layer 104 in an upper portion of the semiconductor layer 103.

Referring to FIG. 2B, the hexagonal boron nitride thin film layer 301 may be provided on the barrier layer 104. The hexagonal boron nitride thin film layer 301 may be grown at, for example, about 1000° C. to 1500° C. by metal organic chemical vapor deposition (MOCVD) to serve as a protection layer. Thereby, the hexagonal boron nitride thin film layer 301 becomes to have improved cosmic resistance than a nitride-based protection layer deposited by chemical vapor deposition (CVD) or an oxide-based protection layer deposited by atomic layer deposition (ALD). The thickness of the hexagonal boron nitride thin film layer 301 may be provided in the range of 1 nm to about 5 nm. The hexagonal boron nitride thin film layer 301 is provided at ultra-low pressure and a high temperature to have excellent thin-film quality and high-quality thin-film characteristics even with a thin thickness of about 1 nm to about 5 nm, and have very strong resistance to the infiltration of chemical materials. Thus, the gallium nitride-based high-power RF device 1000 may be provided with improved radiation resistance.

Referring to FIG. 2C, a first protection layer 302 may be provided on the hexagonal boron nitride thin film layer 301. The first protection layer 302 may serve to protect the hexagonal boron nitride thin film layer 301 in an alignment key provision process to be described below. The first protection layer 302 may include a nitride-based or oxide-based dielectric material. The first protection layer 302 may be deposited on the hexagonal boron nitride thin film layer 301 by, for example, CVD or ALD.

Referring to FIG. 2D, the hexagonal boron nitride thin film layer 301 and the first protection layer 302 on the periphery regions R2 may be etched to provide first holes HL1 in a lithography process. The first holes HL1 may be provided by wet etching, dry etching, or a combination thereof.

Referring to FIG. 2E, a metal may be deposited into the first holes to provide the alignment key 401. The alignment key 401 may be provided through a metal deposition and lift-off process. In order to prevent the alignment key 401 from being removed together with the removal of the first protection layer 302 to be described below, the alignment key 401 may include a metal that is not infiltrated with hydrofluoric acid. The alignment key 401 may include, for example, Ni or Ag.

Referring to FIG. 2F, the hexagonal boron nitride thin film layer 301 and first protection layer 302 on the active region R1 may be etched to provide second holes HL2 in a lithography process. The first protection layer 302 may be etched by hydrofluoric acid-based wet etching, dry etching, or a combination thereof. However, the hexagonal boron nitride thin film layer 301 is very stable against and not etched by the hydrofluoric acid-based wet etching, and thus may be etched by dry etching.

Referring to FIG. 2G, metal patterns 402 may be respectively provided to the second holes. The metal patterns 402 may be provided through a metal deposition and lift-off process. Each of the metal patterns 402 may serve as a source electrode or a drain electrode according to the provision position. Each of the metal patterns 402 may include a metal. For example, each of the metal patterns may include at least one of Ti, Al, Ni, Au, Pd, Cu, Co, or Pt, or an alloy thereof. The metal patterns 402 may be diffused into the barrier layer 104 and the semiconductor layer 103 due to a rapid thermal process to be described below to contact the two-dimensional electron gas layer 201.

Referring to FIG. 2H, the first protection layer 302 may be removed. The first protection layer 302 may be removed by hydrofluoric acid-based wet etching. Here, dry etching is not used. The hexagonal boron nitride thin film layer 301 is very easily etched by dry etching, but is not etched by the hydrofluoric acid-based wet etching. Accordingly, in order to prevent the hexagonal boron nitride thin film layer 301 from being degraded and disappeared due to the removal of the first protection layer 302, the hydrofluoric acid-based wet etching may be used. Thereby, the yield of the gallium nitride-based high-power RF device 1000 may be improved.

The removal of the first protection layer 302 may be performed prior to the provision of the source/drain electrodes 403 through a rapid thermal process after the provision of the metal patterns 402. When the rapid thermal process is performed in a state where the first protection layer 302 remains, the metal patterns 402 may be irregularly diffused into the first protection layer 302 during the diffusion into the barrier layer 104 and the semiconductor layer 103.

Referring to FIG. 2I, an ohmic contact may be provided between the metal patterns 402 and the semiconductor layer 103 through the rapid thermal process. In the rapid thermal process, metal atoms in the metal patterns 402 may be diffused into the barrier layer 104 and the semiconductor layer 103 to provide an alloy. Thereby, the metal patterns 402 may change into the source/drain electrodes 403. The source/drain electrodes 403 may include, for example, a metal silicide. The rapid thermal process may be performed at a temperature lower than that at which the hexagonal boron nitride thin film layer 301 is degraded. The rapid thermal process may be performed at, for example, about 500° C. to 1000° C.

Referring to FIG. 2J, a second protection layer 303 may be provided to cover the hexagonal boron nitride thin film layer 301, the source/drain electrodes 403, and the alignment key 401. The second protection layer 303 may include a dielectric layer of the same nitride-based or oxide-based material as the first protection layer 302. The second protection layer 303 may be deposited by CVD or ALD.

Referring to FIG. 2K, the second protection layer 303 on the peripheral regions R2 may be removed in a lithography process. The second protection layer 303 on the peripheral regions R2 may be removed by wet etching, dry etching, or a combination thereof. FIG. 2K is a cross-sectional view showing a case in which hydrofluoric acid-based wet etching is used to remove the second protection layer 303 on the peripheral regions R2. When using the dry etching, a portion of or the whole hexagonal boron nitride thin film layer 301 may be etched after etching the second protection layer 303 on the peripheral regions R2. However, the hexagonal boron nitride thin film layer 301 on the peripheral regions R2 does not largely affect the performance and radiation resistance of the gallium nitride-based high-power RF device 1000, and thus, unlike the shown in FIG. 2K, the second protection layer 303 may be removed using dry etching.

Referring to FIG. 2L, separation patterns 501 may be provided on the peripheral regions R2 of the substrate 101 through an ion injection process. The separation patterns 501 serve to electrically separate the two-dimensional electron gas layer 201 on the active region R1 from the two-dimensional electron gas layer 201 on the peripheral regions R2. Accordingly, when operating the gallium nitride-based high-power RF device 1000, inter-device interference due to the operation of a nearby device may be minimized. Here, the second protection layer 303 remaining on the active region R1 may serve to protect the active region R1.

Referring to FIG. 2M, the second protection layer 303 on the active regions R1 may be removed. The characteristics of the second protection layer 303 may be degraded in the ion injection process for providing the separation patterns 501. Thus, the degraded second protection layer 303 is required to be removed. The second protection layer 303 may be removed by hydrofluoric acid-based wet etching. When using dry etching, the hexagonal boron nitride thin film layer 301 may be degraded or disappeared by removing the second protection layer 303. It is because the hexagonal boron nitride thin film layer 301 is easily etched by the dry etching. Accordingly, the second protection layer 303 on the active region R1 may be removed by the hydrofluoric acid-based wet etching.

Referring to FIG. 2N, a third protection layer 304 may be provided to cover the hexagonal boron nitride thin film layer 301, the source/drain electrodes 403, the alignment key 401, and the separation patterns 501. The third protection layer 303 may be provided with the same nitride-based or oxide-based dielectric layer as the first protection layer 302 and the second protection layer by CVD or ALD. The third protection layer 304 may serve to protect the hexagonal boron nitride thin film layer 301 in a process for providing the contact pads 404 and the T-gate electrode 405 to be described below.

Referring to FIG. 20, the third protection layer 304 deposited on the source/drain electrodes 403 may be removed through a lithography process. The third protection layer 304 deposited on the source/drain electrodes 403 may be removed by wet etching, dry etching, or a combination thereof. Thereby, the top surfaces of the source/drain electrodes 403 may be exposed.

Referring to FIG. 2P, the contact pads 404 may be respectively provided on the exposed top surfaces of the source/drain electrodes 403. A region to be provided with the contact pads 404 is defined through a lithography process, and the contact pads 404 may be provided through a metal deposition and lift-off process. The contact pads 404 may be provided to facilitate the application of a bias for operating the gallium nitride-based high-power RF device 1000. The contact pads 404 may be physically and electrically connected to the source/drain electrodes 403.

Referring to FIG. 2Q, at least a portion of the third protection layer 304 and the hexagonal boron nitride thin film layer 301 on the active region R1 may be removed to provide a third holes HL3 through a lithography process. The third protection layer 304 may be etched by dry etching, hydrofluoric acid-based wet etching, or a combination thereof. However, the hexagonal boron nitride thin film layer 301 is unable to be removed by the hydrofluoric acid-based wet etching, and thus may be removed by the dry etching.

Referring to FIG. 2R, the T-gate electrode 405 may be provided to the third hole HL3. In order to minimize the resistance and improve the frequency characteristics of the T-gate electrode 405, the T-gate electrode 405 with T-shape may be provided by making the width of the first portion 405b larger than that of the second portion 405t in the first direction D1.

Thereafter, the third protection layer 304 on the active region R1 and the peripheral regions R2 may be removed to provide the gallium nitride-based high-power RF device 1000 of FIG. 1. The third protection layer 304 is deposited with the nitride-based or oxide-based dielectric layer by CVD or ALD, and thus the resistance is not better than that of the hexagonal boron nitride thin film layer 301. Accordingly, the third protection layer 304 is required to be removed in order to improve the radiation resistance of the whole gallium nitride-based high-power RF device 1000. The third protection layer 304 may be etched by the hydrofluoric acid-based wet etching. The hydrofluoric acid-based wet etching does not etch the hexagonal boron nitride thin film layer 301, but may easily etch the third protection layer 304 nearby the first portion 405b of the T-gate electrode 405.

The gallium nitride-based high-power RF device according to the inventive concept may use the hexagonal boron nitride thin film as an oxide layer or a protection layer. The hexagonal boron nitride thin film may include the same materials as the semiconductor layer and the barrier layer of the gallium nitride-based high-power RF device to have the excellent interface characteristics. In addition, the hexagonal boron nitride thin film may be grown at about 1000° C. to about 1500° C. to have the improved thin-film quality. Thereby, the gallium nitride-based high-power RF device having improved cosmic ray tolerance may be provided. In addition, the T-gate electrode of T-shape with the top wider than the bottom may be used in the gallium nitride-based high-power RF device. Thereby, the gallium nitride-based high-power RF device may be provided which has the reduced resistance of the gate electrode and the improved frequency characteristics.

In the method for fabricating a gallium nitride-based high-power RF device according to the inventive concept, the hexagonal boron nitride thin film may be grown on the barrier layer and used to provide the gallium nitride-based high-power RF device. Due to the chemical stability of the hexagonal boron nitride thin film, deposition and removal of the protection layers may be repetitively performed in the fabrication method for a high-power RF device. Thereby, the hexagonal boron nitride thin film may be minimally degraded and disappeared to improve the yield of the gallium nitride-based high-power RF device.

Although the example embodiments of the present invention have been described, it is understood that the present invention may be implemented as other concrete forms without changing the inventive concept or essential features. Therefore, these embodiments as described above are only proposed for illustrative purposes and do not limit the present disclosure.

What is claimed is:

1. A gallium nitride-based high-power RF device comprising:
a substrate comprising peripheral regions disposed in parallel in a first direction and an active region between the peripheral regions;
a semiconductor layer, a barrier layer, and a hexagonal boron nitride thin film layer sequentially laminated on the substrate;
separation patterns disposed on the peripheral regions and penetrating through the hexagonal boron nitride thin film layer, the barrier layer and the semiconductor layer;
source/drain electrodes disposed on the semiconductor layer at edges of the active region and spaced apart from each other; and
a T-gate electrode spaced apart from the source/drain electrodes on the barrier layer and disposed between the source/drain electrodes,
wherein the T-gate electrode comprises
a first portion positioned downside, and
a second portion positioned on the first portion,
wherein a first width of the first portion in the first direction is smaller than a second width of the second portion,
at least a portion of the first portion penetrates through the hexagonal boron nitride thin film layer to be in contact with the barrier layer, and
a bottom surface of the second portion is spaced apart from the hexagonal boron nitride thin film layer.

2. The gallium nitride-based high-power RF device according to claim 1, further comprising a buffer layer between the substrate and the semiconductor layer
wherein the separation patterns extend to penetrate the buffer layer.

3. The gallium nitride-based high-power RF device according to claim 2, wherein the source/drain electrodes are spaced apart from the buffer layer and are respectively spaced apart from the separation patterns.

4. The gallium nitride-based high-power RF device according to claim 2, further comprising an alignment key spaced apart from the separation patterns on the peripheral regions and penetrating through the hexagonal boron nitride thin film layer to be in contact with the barrier layer.

5. The gallium nitride-based high-power RF device according to claim 1, wherein the thickness of the hexagonal boron nitride thin film layer is about 1 nm to about 5 nm.

6. The gallium nitride-based high-power RF device according to claim 1, further comprising a two-dimensional electron gas layer disposed adjacent to the barrier layer and on the upper portion of the semiconductor layer.

7. The gallium nitride-based high-power RF device according to claim 6, wherein the source/drain electrodes penetrate through the two-dimensional electron gas layer to extend to the semiconductor layer.

8. The gallium nitride-based high-power RF device according to claim 1, wherein the separation patterns are in contact with the substrate.

9. The gallium nitride-based high-power RF device according to claim 1, further comprising contact pads respectively being in contact with top surfaces of the source/drain electrodes.

10. A method for fabricating a gallium nitride-based high-power RF device comprising:
sequentially providing a buffer layer, a semiconductor layer, and a barrier layer on a substrate including peripheral regions and an active region;
providing a hexagonal boron nitride thin film layer on the barrier layer;
providing a first protection layer on the hexagonal boron nitride thin film layer;
providing, on the peripheral regions, an alignment key penetrating through at least a portion of each of the first protection layer and the hexagonal boron nitride thin film layer on the peripheral regions;
providing, at edges of the active region, metal patterns penetrating through at least a portion of each of the first protection layer and the hexagonal boron nitride thin film layer;
removing the first protection layer on the hexagonal boron nitride thin film layer, the alignment key, and the metal patterns;
performing a thermal process to provide ohmic contact between the metal patterns and the semiconductor layer and change the metal patterns to source/drain electrodes;
providing a second protection layer to cover the hexagonal boron nitride thin film layer, the alignment key, and the source/drain electrodes;
providing a T-gate electrode penetrating at least a portion of each of the second protection layer and the hexagonal boron nitride thin film layer between the source/drain electrodes; and
removing the second protection layer.

11. The method for fabricating a gallium nitride-based high-power RF device according to claim 10,
wherein the providing of the alignment key comprises removing at least a portion of the hexagonal boron nitride thin film layer by dry etching to provide a first hole,
wherein the alignment key is disposed in the first hole.

12. The method for fabricating a gallium nitride-based high-power RF device according to claim 10, further comprising, prior to the providing of the second protection layer and after the providing of the source/drain electrodes:
providing a third protection layer;
etching the third protection layer on the peripheral regions;
providing separation patterns defining the active region between the alignment key and the source/drain electrode on the peripheral regions; and
removing the third protection layer.

13. The method for fabricating a gallium nitride-based high-power RF device according to claim 12, wherein the removing of the third protection layer is performed by wet etching.

14. The method for fabricating a gallium nitride-based high-power RF device according to claim 10, further comprising, prior to the providing of the T-gate electrode:
removing the second protection layer on the source/drain electrodes to expose top surfaces of the source/drain electrodes; and
providing contact pads respectively being in contact with the top surfaces of the source/drain electrodes.

15. The method for fabricating a gallium nitride-based high-power RF device according to claim 10, wherein the hexagonal boron nitride thin film layer is provided at a temperature of about 1000° C. to about 1500° C. using metal organic chemical vapor deposition (MOCVD).

16. The method for fabricating a gallium nitride-based high-power RF device according to claim 10, wherein the removing of the first protection layer is performed by wet etching.

17. The method for fabricating a gallium nitride-based high-power RF device according to claim 10, wherein the removing of the second protection layer is performed by wet etching.

18. The method for fabricating a gallium nitride-based high-power RF device according to claim 10,
wherein the providing of the metal patterns comprises removing at least a portion of the hexagonal boron nitride thin film layer by dry etching to provide second holes,
wherein the metal patterns are disposed in the second holes.

19. The method for fabricating a gallium nitride-based high-power RF device according to claim 10,
wherein the providing of the T-gate electrode comprises removing at least a portion of the hexagonal boron nitride thin film layer by dry etching to provide a third hole,
wherein the T-gate electrode is disposed in the third hole.

20. The method for fabricating a gallium nitride-based high-power RF device according to claim 10, wherein the thermal process is performed at a temperature of about 500° C. to about 1000° C.
